(19) United States
(12) Patent Application Publication
(10) Pub. No.: US 2016/0365908 A1
(43) Pub. Date: Dec. 15, 2016

(54) ANTENNA SWAP ARCHITECTURES FOR TIME-DIVISION DUPLEXING COMMUNICATION SYSTEMS

(71) Applicant: SKYWORKS SOLUTIONS, INC., Woburn, MA (US)

(72) Inventors: Weiheng CHANG, Thousand Oaks, CA (US); David Richard PEHLKE, Westlake Village, CA (US)

(21) Appl. No.: 15/177,963

(22) Filed: Jun. 9, 2016

Related U.S. Application Data
(60) Provisional application No. 62/173,833, filed on Jun. 10, 2015.

(51) Int. Cl. H04B 7/06; H03F 3/19; H04L 5/14

(52) U.S. Cl. CPC H04B 7/0602; H04L 5/14; H03F 3/19; H03F 2200/451; H03F 2200/294

(57) ABSTRACT

Antenna swap architectures for time-division duplexing communication systems. In some embodiments, an antenna routing architecture can include first nodes including a transmit (Tx) node, a primary receive (PRx) node and a diversity receive (DRx) node. The antenna routing architecture can further include second nodes including a main antenna node and a diversity antenna node. The antenna routing architecture can further include a routing circuit configured to provide one or more radio-frequency (RF) signal paths between the first nodes and the second nodes. The routing circuit can be further configured such that each of the Tx node and the PRx node is capable of being independently coupled to the main antenna node or the diversity antenna node.

### CROSS-REFERENCE TO RELATED APPLICATION(S)

This application claims priority to U.S. Provisional Application No. 62/173,833 filed Jun. 10, 2015, entitled ANTENNA SWAP ARCHITECTURES FOR TIME-DIVISION DUPLEXING COMMUNICATION SYSTEMS, the disclosure of which is hereby expressly incorporated by reference herein in its entirety.

### BACKGROUND

### Field

The present disclosure relates to communication systems having duplexing capability.

### Description of the Related Art

In some radio-frequency (RF) applications, uplink operations such as transmit operations and downlink operations such as receive operations can be performed generally concurrently. For example, time-division duplexing (TDD) utilizes a configuration where uplink operation and downlink operation can be performed approximately concurrently by use of different time slots in a given frequency band. In another example, frequency-division duplexing (FDD) utilizes a configuration where two different and sufficiently separated frequencies are utilized for uplink and downlink operations.

### SUMMARY

According to a number of implementations, the present disclosure relates to an antenna routing architecture that includes first nodes including a transmit (Tx) node, a primary receive (PRx) node and a diversity receive (DRx) node, and second nodes including a main antenna node and a diversity antenna node. The antenna routing architecture further includes a routing circuit configured to provide one or more radio-frequency (RF) signal paths between the first nodes and the second nodes. The routing circuit is further configured such that each of the Tx node and the PRx node is capable of being independently coupled to the main antenna node or the diversity antenna node.

In some embodiments, the routing circuit can be further configured to include duplexing functionality. The duplexing functionality can include time-division duplexing (TDD) functionality. The PRx node can be coupled to the main antenna node, and the DRx node can be coupled to the diversity antenna node.

In some embodiments, the PRx node can be always coupled to the main antenna node, and the DRx node can be always coupled to the diversity antenna node. In some embodiments, the routing circuit can include a first switching circuit configured to couple the Tx node to the main antenna node or the diversity antenna node. The first switching circuit can be further configured to provide the coupling of the PRx node to the main antenna node, and to provide the coupling of the DRx node to the diversity antenna node.

In some embodiments, the routing circuit can include a first TDD filter implemented between the first switching circuit and the main antenna node. The first TDD filter can be configured to allow TDD operation involving an amplified Tx signal associated with the Tx node and an Rx signal associated with the PRx node when the main antenna node is being utilized for the TDD operation.

In some embodiments, the routing circuit can further include a lossy path between the first switching circuit and the DRx node. The routing circuit can further include a low-noise amplifier (LNA) implemented between the lossy path and the DRx node, and the LNA can be configured to provide amplification for an Rx signal received through the DRx node.

In some embodiments, the routing circuit can further include a switchable path configured to selectively bypass the LNA. The routing circuit can include a bypass switch assembly implemented to allow routing of the Rx signal from the DRx node to the LNA, or to allow routing of an amplified Tx signal associated with the Tx node through the switchable bypass path. The bypass switch assembly can include a first switch between the DRx node and the LNA, and a second switch parallel with the first switch and between the DRx node and the lossy path.

In some embodiments, the first switch can be the only switch between the DRx node and the LNA, such that the Rx signal experiences a relatively low loss due to the only switch. The bypass switch assembly can further include a third switch between the LNA and the lossy path. In some embodiments, the second switch can be the only switch between the lossy path and the DRx node, such that the amplified Tx signal experiences a relatively low loss due to the only switch.

In some embodiments, the routing circuit can further include a second TDD filter implemented between the first bypass switch and the DRx node. The second TDD filter can be configured to allow TDD operation involving the amplified Tx signal and the Rx signal from the DRx node when the diversity antenna node is being utilized for the TDD operation. The first switching circuit and the bypass switch assembly can be configured to operate in cooperation to allow TDD operation involving the amplified Tx signal associated with the Tx node and the Rx signal associated with the DRx node when the diversity antenna node is being utilized for the TDD operation.

In some embodiments, the routing circuit can include a first switching circuit and a second switching circuit configured to couple the Tx node to the main antenna node or the diversity antenna node. The routing circuit can include a first TDD filter implemented between the first switching circuit and the second switching circuit. The first TDD filter can be configured to allow TDD operation involving an amplified Tx signal associated with the Tx node and an Rx signal associated with the PRx node when the main antenna node is being utilized for the TDD operation.

In some embodiments, the first switching circuit and the second switching circuit can be further configured to provide the coupling of the PRx node to the main antenna node. The second switching circuit can be further configured to provide the coupling of the DRx node to the diversity antenna node. The routing circuit can further include a lossy path between the second switching circuit and the DRx node. The routing circuit can further include a low-noise amplifier (LNA) and a second TDD filter implemented between the lossy path and the DRx node, with the LNA being configured to provide amplification for an Rx signal received through the DRx node. The routing circuit can further include a switchable path configured to selectively bypass the second TDD filter and the LNA. The routing circuit can include a bypass switch assembly implemented to allow routing of the Rx signal from the DRx node to the second TDD filter and the LNA, or to allow routing of an amplified Tx signal associated with the Tx node through the switchable bypass path. The bypass switch assembly can include a first switch between the DRx node and the second TDD filter, and a second switch parallel with the first switch and between the DRx node and the lossy path.

In some embodiments, the first switch can be the only switch between the DRx node and the LNA, such that the Rx signal experiences a relatively low loss due to the only switch. The bypass switch assembly can further include a third switch between the LNA and the lossy path. In some embodiments, the second switch can be the only switch between the lossy path and the DRx node, such that the amplified Tx signal experiences a relatively low loss due to the only switch.

In some embodiments, the second TDD filter can be configured to provide filtering functionality for the LNA. The second switching circuit and the bypass switch assembly can be configured to operate in cooperation to allow TDD operation involving the amplified Tx signal associated with the Tx node and the Rx signal associated with the DRx node when the diversity antenna node is being utilized for the TDD operation.

In some embodiments, the first and second switching circuits can be further configured to provide the coupling of the DRx node to the diversity antenna node. The routing circuit can further include a PRx/DRx switching circuit implemented between the first switching circuit and the PRx and DRx nodes. The PRx/DRx switching circuit can be configured to allow a DRx signal to be output to the DRx node even if it was obtained from the main antenna node, and to allow a PRx signal to be output to the PRx node even if it was obtained from the diversity antenna node. The PRx/DRx switching circuit can include a cross-point configuration.

In some embodiments, the routing circuit can further include a lossy path between the second switching circuit and the DRx node. The routing circuit can further include a low-noise amplifier (LNA) and a second TDD filter implemented between the lossy path and the DRx node, and the LNA can be configured to provide amplification for an Rx signal received through the DRx node.

In some embodiments, the routing circuit can further include a switchable path configured to selectively bypass the second TDD filter and the LNA. The routing circuit can include a bypass switch assembly implemented to allow routing of the Rx signal from the DRx node to the second TDD filter and the LNA, or to allow routing of an amplified Tx signal associated with the Tx node through the switchable bypass path. The bypass switch assembly can include a first switch between the DRx node and the second TDD filter, and a second switch parallel with the first switch and between the DRx node and the lossy path. The first switch can be the only switch between the DRx node and the LNA, such that the Rx signal experiences a relatively low loss due to the only switch. The bypass switch assembly can further include a third switch between the LNA and the lossy path. The second switch can be the only switch between the lossy path and the DRx node, such that the amplified Tx signal experiences a relatively low loss due to the only switch.

In some embodiments, the second TDD filter can be configured to provide filtering functionality for the LNA. The second switching circuit and the bypass switch assembly can be configured to operate in cooperation to allow TDD operation involving the amplified Tx signal associated with the Tx node and the Rx signal associated with the DRx node when the diversity antenna node is being utilized for the TDD operation.

In some implementations, the present disclosure relates to a time-division duplexing (TDD) architecture that includes a primary path configured for TDD operations involving a main antenna. The primary path has a single filter configured to support the TDD operations including a transmit (Tx) operation and a primary receive (PRx) operation with the main antenna. The TDD architecture further includes a diversity path configured for TDD operations involving a diversity antenna. The diversity path has a single filter configured to support the TDD operations including the Tx operation and a diversity receive (DRx) operation with the diversity antenna.

According to some teachings, the present disclosure relates to a method for performing time-division duplexing (TDD) of radio-frequency (RF) signals. The method includes maintaining a primary receive (PRx) connectivity to a main antenna, maintaining a diversity receive (DRx) connectivity to a diversity antenna, and swapping a transmit (Tx) connectivity between the main antenna and the diversity antenna.

In some embodiments, the swapping of the Tx connectivity can be performed without changing the PRx connectivity.

In a number of implementations, the present disclosure relates to a time-division duplexing (TDD) architecture having a primary path configured for TDD operations involving a main antenna, and a diversity path configured for TDD operations involving a diversity antenna. The TDD architecture further includes a first switching circuit configured to allow a transmit (Tx) signal to be routed to the main antenna or the diversity antenna, and a second switching circuit configured to allow a primary receive (PRx) signal to be obtained from the diversity antenna and be output to a PRx pin, and to allow a diversity receive (DRx) signal to be obtained from the main antenna and be output to a DRx pin.

In some implementations, the present disclosure relates to a wireless device that includes a transceiver configured to process radio-frequency (RF) signals, a main antenna and a diversity antenna, each in communication with the transceiver, and an antenna routing system implemented between the transceiver and the main and diversity antennas. The antenna routing system includes first nodes having a transmit (Tx) node, a primary receive (PRx) node and a diversity receive (DRx) node. The antenna routing system further includes second nodes having a main antenna node and a diversity antenna node. The antenna routing system further includes a routing circuit configured to provide one or more RF signal paths between the first nodes and the second nodes. The routing circuit is further configured such that each of the Tx node and the PRx node is capable of being independently coupled to the main antenna node or the diversity antenna node.

According to some implementations, the present disclosure relates to a wireless device having a transceiver configured to process radio-frequency (RF) signals, a main antenna and a diversity antenna, each in communication with the transceiver, and a time-division duplexing (TDD) architecture including a primary path configured for TDD operations involving the main antenna. The primary path has a single filter configured to support the TDD operations including a transmit (Tx) operation and a primary receive (PRx) operation with the main antenna. The TDD architecture further includes a diversity path configured for TDD operations involving the diversity antenna. The diversity path has a single filter configured to support the TDD operations including the Tx operation and a diversity receive (DRx) operation with the diversity antenna.

In some implementations, the present disclosure relates to a wireless device having a transceiver configured to process radio-frequency (RF) signals, a main antenna and a diversity antenna, each in communication with the transceiver, and a time-division duplexing (TDD) architecture including a primary path configured for TDD operations involving the main antenna, and a diversity path configured for TDD operations involving the diversity antenna. The TDD architecture further includes a first switching circuit configured to allow a transmit (Tx) signal to be routed to the main antenna or the diversity antenna. The TDD architecture further includes a second switching circuit configured to allow a primary receive (PRx) signal to be obtained from the diversity antenna and be output to a PRx pin in communication with the transceiver, and to allow a diversity receive (DRx) signal to be obtained from the main antenna and be output to a DRx pin in communication with the transceiver.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a block diagram of an antenna routing system or architecture configured to operate with a first antenna and a second antenna.

FIG. 2 shows that the first antenna and the second antenna of FIG. 1 can be a main antenna and a diversity antenna.

FIG. 3 shows a block diagram of an antenna routing system configured to utilize a main antenna and a diversity antenna.

FIG. 4A shows the antenna routing system of FIG. 3 in a first mode.

FIG. 4B shows the antenna routing system of FIG. 3 in a second mode.

FIG. 5 shows an example of a frequency-division duplexing (FDD) architecture in which transmit (Tx) and primary receive (PRx) operations are tied together through a common Tx/PRx path when being coupled to either of main and diversity antennas.

FIG. 6 shows an example of a time-division duplexing (TDD) architecture in which Tx and PRx operations are tied together through a common Tx/PRx path when being coupled to either of main and diversity antennas.

FIG. 7 shows that in some embodiments, an antenna routing system or architecture can include a duplexing system configured to provide independent routing of radio-frequency (RF) signals associated with Tx and PRx operations.

FIG. 8 shows an example TDD antenna routing system that can be implemented with a reduced number of filters.

FIG. 9A shows an example configuration in which the TDD antenna routing system of FIG. 8 utilizes a main antenna for Tx operation.

FIG. 9B shows an example configuration in which the TDD antenna routing system of FIG. 8 utilizes a diversity antenna for Tx operation.

FIG. 10 shows an example of a switching configuration that can be implemented for the examples of FIGS. 8 and 9.

FIG. 11A shows an example of how the switching configuration of FIG. 10 can be operated when a low-noise amplifier (LNA) is being utilized.

FIG. 11B shows an example of how the switching configuration of FIG. 10 can be operated when the LNA is being bypassed.

FIG. 12 shows another example TDD antenna routing system that can be implemented with a reduced number of filters.

FIG. 13A shows an example configuration in which the TDD antenna routing system of FIG. 12 utilizes a main antenna for Tx operation.

FIG. 13B shows an example configuration in which the TDD antenna routing system of FIG. 12 utilizes a diversity antenna for Tx operation.

FIG. 14 shows an example of a switching configuration that can be implemented for the examples of FIGS. 12 and 13.

FIG. 15A shows an example in which the switching configuration of FIG. 14 can be operated when an LNA is being utilized.

FIG. 15B shows an example in which the switching configuration of FIG. 14 can be operated when the LNA is being bypassed.

FIG. 16 shows yet another example TDD antenna routing system that can be implemented with a reduced number of filters.

FIG. 17 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

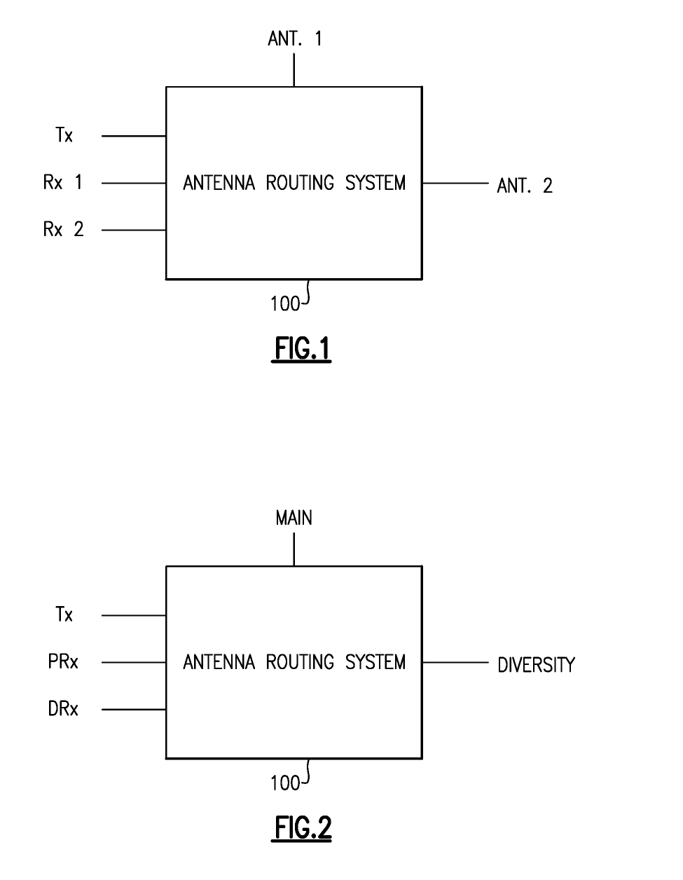

FIG. 1 shows a block diagram of an antenna routing system or architecture 100 having one or more features as described herein. Such an architecture can be configured to route radio-frequency (RF) signals between a plurality of nodes associated with transmit (Tx) and receive (Rx) operations and a plurality of antenna nodes. It will be understood that such antenna nodes can be connected to their respective antennas.

In the example of FIG. 1, the plurality of nodes associated with Tx and Rx operations are indicated as “Tx” for a transmit portion of a first frequency band, “Rx 1” for a receive portion of the first frequency band, and “Rx 2” for a receive portion of a second frequency band. RF signals associated with such nodes can be routed to and/or from a first antenna (Ant. 1) and a second antenna (Ant. 2). In some embodiments, the TX and Rx 1 operations can be serviced with the first antenna, and the Rx 2 operation can be serviced with the second antenna. However, there may be situations where one or more swapping of antenna assignments for the Tx, Rx 1 and Rx 2 operations is/are desirable. As described herein, the antenna routing architecture 100 as described herein can provide such antenna swapping functionality in an efficient manner.

FIG. 2 shows that in some embodiments, the first antenna (Ant. 1) and the second antenna (Ant. 2) of FIG. 1 can be a main antenna (Main) and a diversity antenna (Diversity). In such a context, Tx and Rx 1 can be transmit and receive portions of a primary frequency band primarily assigned to operate with the main antenna. Rx 2 can be a receive portion of a diversity frequency band assigned to operate with the diversity antenna. Accordingly, for the purpose of description, Rx 1 and Rx 2 can be indicated as PRx (primary receive) and DRx (diversity receive), respectively.

In an example context of wireless handsets such as cellular mobile devices, it is noted that such handsets are typically designed to have one antenna system on one end of the phone, and another antenna system on the other end. Such a configuration is designed to support multiple radio coexistence with increased isolation, and to achieve required or desired envelope correlation performance between intended independent antennas. Such support of multiple receivers for each active receive (Rx) link typically involves simultaneous primary Rx (PRx) and diversity Rx (DRx) operations on these two antenna systems at the same time.

To optimize or improve Rx performance, a low-noise amplifier (LNA) is preferably implemented as close as possible to each antenna to thereby reduce loss before the LNA, and to increase overall Rx signal-to-noise ratio (SNR). Such an LNA typically has a filter implemented before it to attenuate blocking signals that can exceed the LNA's linearity limits.

In the foregoing configuration with the near and remote antenna systems on either sides of the handset, it is desirable to be able to switch between these two antennas in an event that one of the antennas is in a state (e.g., loaded, obscured, and/or detuned) that does not allow the intended balance of ideal operation. Such a swap of antennas is typically required for transmit (Tx) operation, so that an amplified RF signal is routed to one of the two antennas.

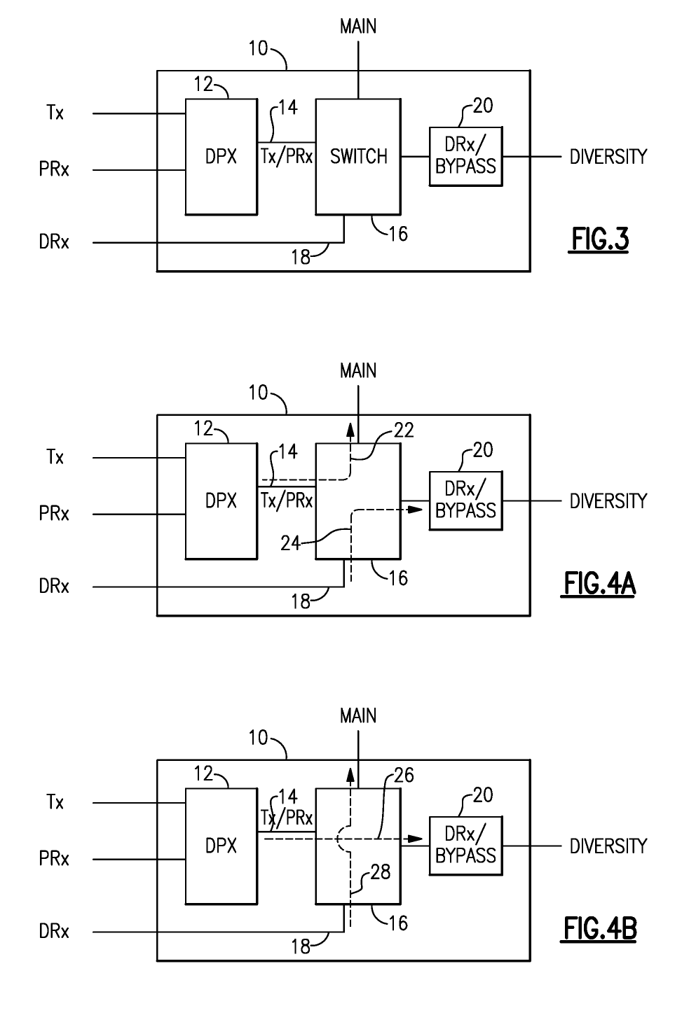

FIG. 3 shows a block diagram of an antenna routing system 10 configured to utilize a main antenna (Main) and a diversity antenna (Diversity). The antenna routing system 10 can route RF signals associated with Tx, PRx and DRx operations through various circuits therein. For example, the Tx and PRx operations can be duplexed by a duplexer circuit 12 so as to allow use of a common path 14 that supports both Tx and PRx operations. Such a common Tx/PRx path is shown to be coupled to a switch circuit 16 that can allow routing between the common Tx/PRx path 14 and either of the main and diversity antennas.

In the example of FIG. 3, the DRx operation is shown to be supported by a diversity path 18 coupled to the switch circuit 16. The switch circuit 16 can also allow routing between the diversity path 18 and either of the main and diversity antennas.

In the example of FIG. 3, a path between the switch circuit 16 and the diversity antenna can include a circuit 20 configured to support the DRx operation or a bypass mode (e.g., when the diversity antenna is being used for non-DRx operation). Examples of such a circuit are described herein in greater detail.

FIG. 4A shows the antenna routing system 10 of FIG. 3 in a first mode in which the common Tx/PRx path 14 is coupled to the main antenna (depicted as signal route 22), and the diversity path 18 is coupled to the diversity antenna (depicted as signal route 24), by the switch circuit 16. FIG. 4B shows the same antenna routing system 10 in a second mode in which the common Tx/PRx path 14 is coupled to the diversity antenna (depicted as signal route 26), and the diversity path 18 is coupled to the main antenna (depicted as signal route 28), by the switch circuit 16.

It is noted that in both of the first and second modes of FIGS. 4A and 4B, the Tx and PRx operations are tied together through the common Tx/PRx path 14. As described herein, when such a constraint is removed, a number of antenna swapping configurations having desirable features can be implemented.

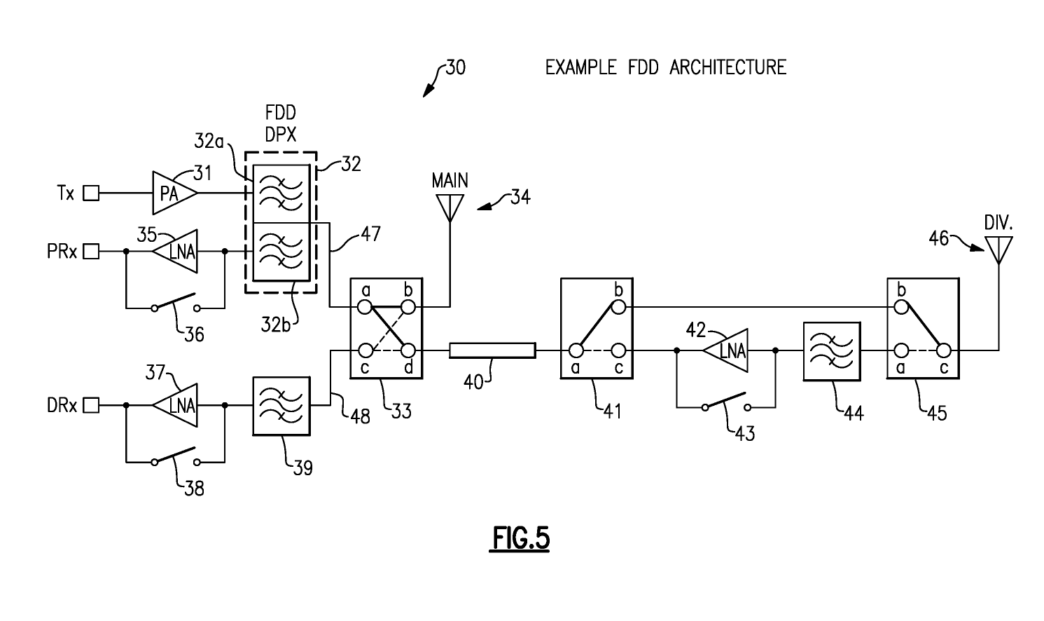

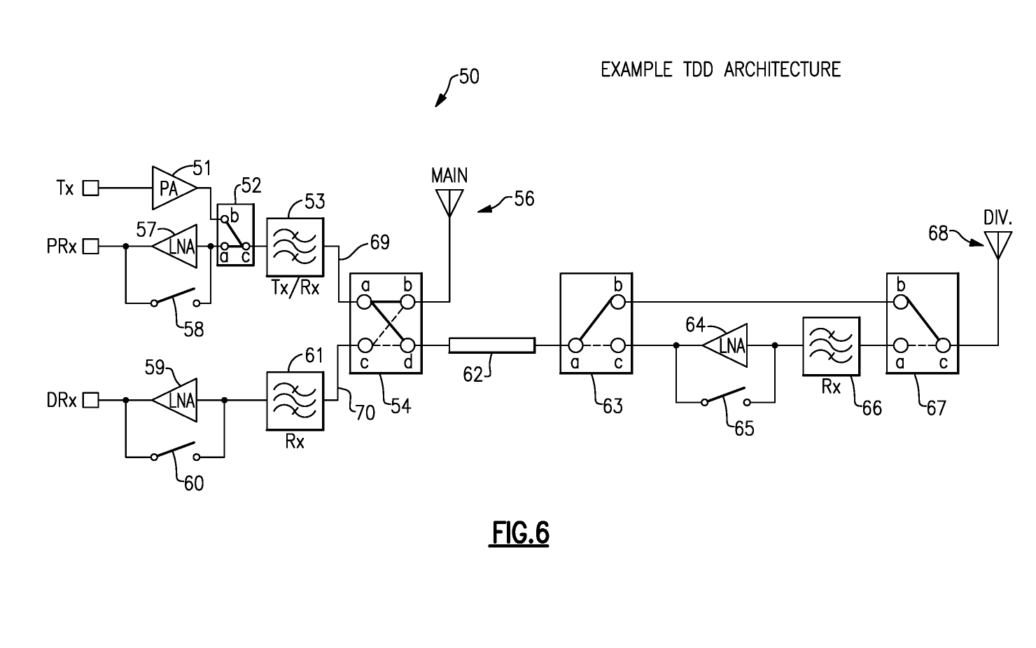

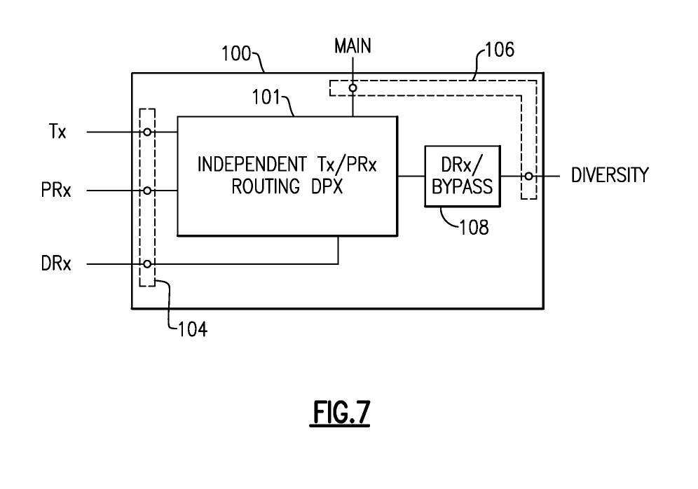

In the examples of FIGS. 3 and 4, the duplexing (DPX) functionality between Tx and PRx operations can be frequency-division duplexing (FDD) or time-division duplexing (TDD). FIG. 5 shows an example of an FDD architecture in which Tx and PRx operations are tied together through a common Tx/PRx path when being coupled to either of the main and diversity antennas. Similarly, FIG. 6 shows an example of a TDD architecture in which Tx and PRx operations are tied together through a common Tx/PRx path when being coupled to either of the main and diversity antennas.

In FIG. 5, an example FDD architecture 30 is shown to include a switch circuit 33 that can couple a common Tx/PRx path 47 to a main antenna 34 or a diversity antenna 46. For example, switch nodes 33a and 33b can be connected (depicted as a solid line) to provide a route between the common Tx/PRx path 47 and the main antenna 34. Similarly, switch nodes 33a and 33d can be connected (depicted as a solid line) to provide a route between the common Tx/PRx path 47 and the diversity antenna 46.

The switch circuit 33 can also couple a diversity path 48 to the main antenna 34 or the diversity antenna 46. For example, switch nodes 33c and 33d can be connected (depicted as a dashed line) to provide a route between the diversity path 48 and the diversity antenna 46. Similarly, switch nodes 33c and 33b can be connected (depicted as a dashed line) to provide a route between the diversity path 48 and the main antenna 34.

In the example of FIG. 5, the common Tx/PRx path 47 is shown to be coupled to Tx and PRx nodes through an FDD duplexer 32 (having a Tx filter 32a and an Rx filter 32b). The Tx portion of the duplexer 32 is shown to be coupled to an output of a power amplifier (PA) 31. The Rx portion of the duplexer 32 is shown to be coupled to an input of an LNA 35. A bypass path can be provided for the LNA 35 utilizing a switch 36.

In the example of FIG. 5, the diversity path 48 is shown to be coupled to a DRx node through a filter 39 and an LNA 37. A bypass path can be provided for the LNA 37 utilizing a switch 38. In the example shown, the LNA 37 can be operational (with switch 38 open) when the diversity path 48 is coupled to the main antenna 34, or be non-operational (with switch 38 closed to provide bypass) when the diversity path 48 is coupled to the diversity antenna 46. Such turning off of the LNA 37 in the latter example can be achieved when there is an LNA near the diversity antenna, as shown in the example of FIG. 5.

In the example of FIG. 5, the switch node 33d of the switch circuit 33 is shown to be coupled to the diversity antenna 46 through a switch circuit 45, a filter 44, an LNA 42, a switch circuit 41, and a relatively lengthy and lossy path indicated as 40.

In the example of FIG. 5, switch nodes 45c and 45a of the switch circuit 45 can be connected (depicted as a dashed line), and switch nodes 41c and 41a of the switch circuit 41 can be connected (depicted as a dashed line), when the DRx operation is being performed through the diversity antenna 46. In such a mode, the LNA 42 can be operational (with switch 43 open), and the downstream LNA 37 may or may not be operational.

In the example of FIG. 5, switch nodes 45c and 45b of the switch circuit 45 can be connected (depicted as a solid line), and switch nodes 41b and 41a of the switch circuit 41 can be connected (depicted as a solid line), when the duplexed Tx/PRx operations are being performed through the diversity antenna 46. In such a mode, the filter 44 and the LNA 42 can be bypassed through a bypass path between the switch nodes 45b and 41b.

In FIG. 6, an example TDD architecture 50 is shown to include a switch circuit 54 that can couple a common Tx/PRx path 69 to a main antenna 56 or a diversity antenna 68. For example, switch nodes 54a and 54b can be connected (depicted as a solid line) to provide a route between the common Tx/PRx path 69 and the main antenna 56. Similarly, switch nodes 54a and 54d can be connected (depicted as a solid line) to provide a route between the common Tx/PRx path 69 and the diversity antenna 68.

The switch circuit 54 can also couple a diversity path 70 to the main antenna 56 or the diversity antenna 68. For example, switch nodes 54c and 54d can be connected (depicted as a dashed line) to provide a route between the diversity path 70 and the diversity antenna 68. Similarly, switch nodes 54c and 54b can be connected (depicted as a dashed line) to provide a route between the diversity path 70 and the main antenna 56.

In the example of FIG. 6, the common Tx/PRx path 69 is shown to be coupled to Tx and PRx nodes through a Tx/Rx filter 53 and a Tx/Rx switch 52. The Tx/Rx switch 52 can be operated so as to provide TDD functionality between Tx and PRx modes. For example, switch node 52c can be connected to switch node 52b for Tx operation, or to switch node 52a for PRx operation in a switching sequence. Accordingly, when the switch nodes 52c and 52b are connected for Tx operation, an output of a PA 51 can be connected to the Tx/Rx filter 53. Similarly, when the switch nodes 52c and 52a are connected for PRx operation, the Tx/Rx filter 53 can be connected to an input of an LNA 57. A bypass path can be provided for the LNA 57 utilizing a switch 58.

In the example of FIG. 6, the diversity path 70 is shown to be coupled to a DRx node through a filter 61 and an LNA 59. A bypass path can be provided for the LNA 59 utilizing a switch 60. In the example shown, the LNA 59 can be operational (with switch 60 open) when the diversity path 70 is coupled to the main antenna 56, or be non-operational (with switch 60 closed to provide bypass) when the diversity path 70 is coupled to the diversity antenna 68. Such turning off of the LNA 59 in the latter example can be achieved when there is an LNA near the diversity antenna, as shown in the example of FIG. 6.

In the example of FIG. 6, the switch node 54d of the switch circuit 54 is shown to be coupled to the diversity antenna 68 through a switch circuit 67, a filter 66, an LNA 64, a switch circuit 63, and a relatively lengthy and lossy path indicated as 62.

In the example of FIG. 6, switch nodes 67c and 67a of the switch circuit 67 can be connected (depicted as a dashed line), and switch nodes 63c and 63a of the switch circuit 63 can be connected (depicted as a dashed line), when the DRx operation is being performed through the diversity antenna 68. In such a mode, the LNA 64 can be operational (with switch 65 open), and the downstream LNA 59 may or may not be operational.

In the example of FIG. 6, switch nodes 67c and 67b of the switch circuit 67 can be connected (depicted as a solid line), and switch nodes 63b and 63a of the switch circuit 63 can be connected (depicted as a solid line), when the duplexed Tx/PRx operations are being performed through the diversity antenna 68. In such a mode, the filter 66 and the LNA 64 can be bypassed through a bypass path between the switch nodes 67b and 63b.

In the examples of FIGS. 3-6, duplexed Tx/PRx operations (in FDD or TDD mode) are tied together through a common Tx/PRx path. Accordingly, the PRx operation depends on such a common Tx/PRx path, and therefore on Tx operation.

FIG. 7 shows that in some embodiments, an antenna routing system or architecture 100 can include a duplexing system 101 configured to provide independent routing of RF signals associated with Tx and PRx operations. For the purpose of description, it will be understood that such independent routing can include a configuration where Tx and PRx operations do not necessarily need to be associated together with a given antenna (e.g., main antenna or diversity antenna). It will also be understood that such independent routing may or may not include a common signal path utilized by both Tx and PRx operations.

In the example of FIG. 7, the duplexing system 101 is shown to provide various routing of RF signals between a plurality of input/output (I/O) nodes 104 and a plurality of antenna nodes 106. The I/O nodes 104 can include Tx and PRx nodes corresponding to a duplexed frequency band(s), and a DRx node corresponding to a diversity frequency band. For the purpose of description, the Tx node can be on the input side or the output side of a PA. Similarly, the PRx node can be on the input side or the output side of an LNA. Similarly, the DRx node can be on the input side or the output side of an LNA, if such an LNA exists. Also for the purpose of description, the antenna nodes 106 can be nodes implemented on one or more modules (e.g., on a common module or on separate modules), nodes implemented in a circuit board such as a phone board, or any combination thereof, where such nodes are connected to or connectable to their respective antennas.

In the example of FIG. 7, the antenna routing system 100 is shown to further include a DRx circuit 108 having bypass capability. Examples related to such a circuit are described herein in greater detail.

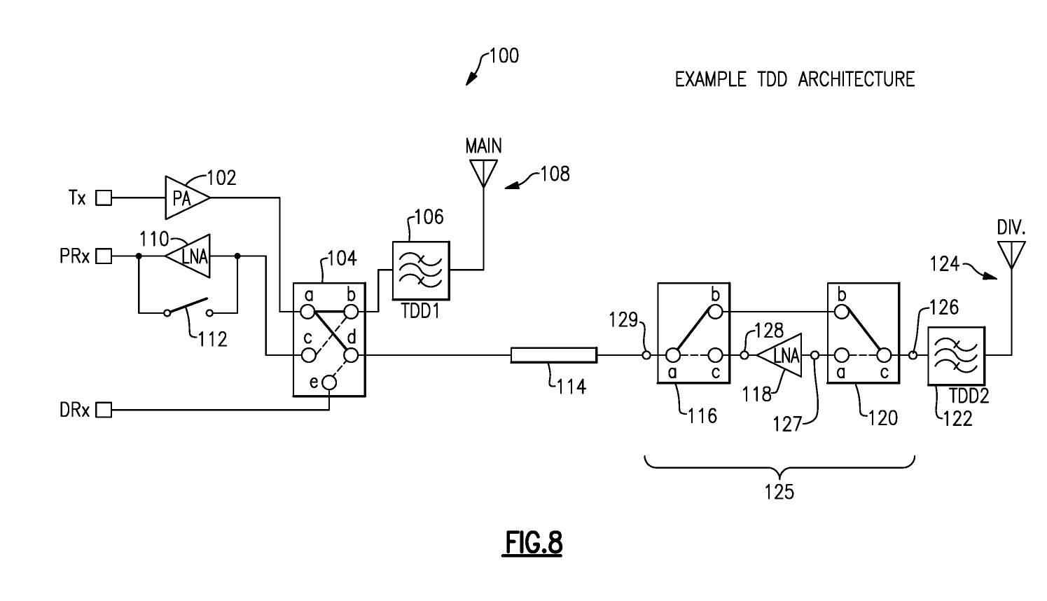

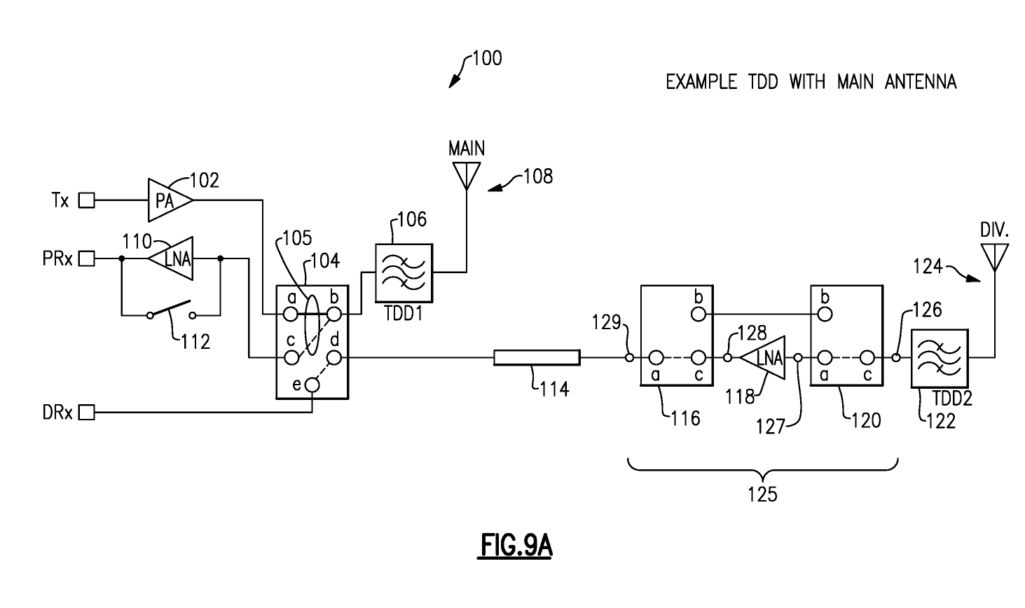

In some embodiments, the antenna routing system 100 of FIG. 7 can be implemented as a TDD system. FIGS. 8-16 show various examples of such a TDD system.

FIG. 8 shows an example TDD antenna routing system 100 that can be implemented with a reduced number of filters. Such an antenna routing system 100 can include a switching circuit 104 configured to provide both Tx/Rx TDD functionality, as well as antenna selection functionality. For example, switch node 104a of the switching circuit 104 can be coupled to a Tx node through a PA 102, and switch node 104c of the switching circuit 104 can be coupled to a PRx node through an LNA 110. A bypass path can be provided for the LNA 110 utilizing a switch 112. Switch node 104b of the switching circuit 104 can be coupled to a main antenna 108 through a first TDD filter (TDD1) 106. Switch node 104d of the switching circuit 104 can be coupled to a diversity antenna 124 through a second TDD filter (TDD2) 122, a switch circuit 120, an LNA 118, a switch circuit 116, and a relatively lengthy and lossy path indicated as 114. Switch node 104e of the switching circuit 104 can be coupled to a DRx node.

In the example of FIG. 8, PRx operation can be assigned to the main antenna 108. Accordingly, switch node 104b is shown to be connected to switch node 104c (depicted as a dashed line). Similarly, DRx operation can be assigned to the diversity antenna 124. Accordingly, switch node 104d is shown to be connected to switch node 104e (depicted as a dashed line).

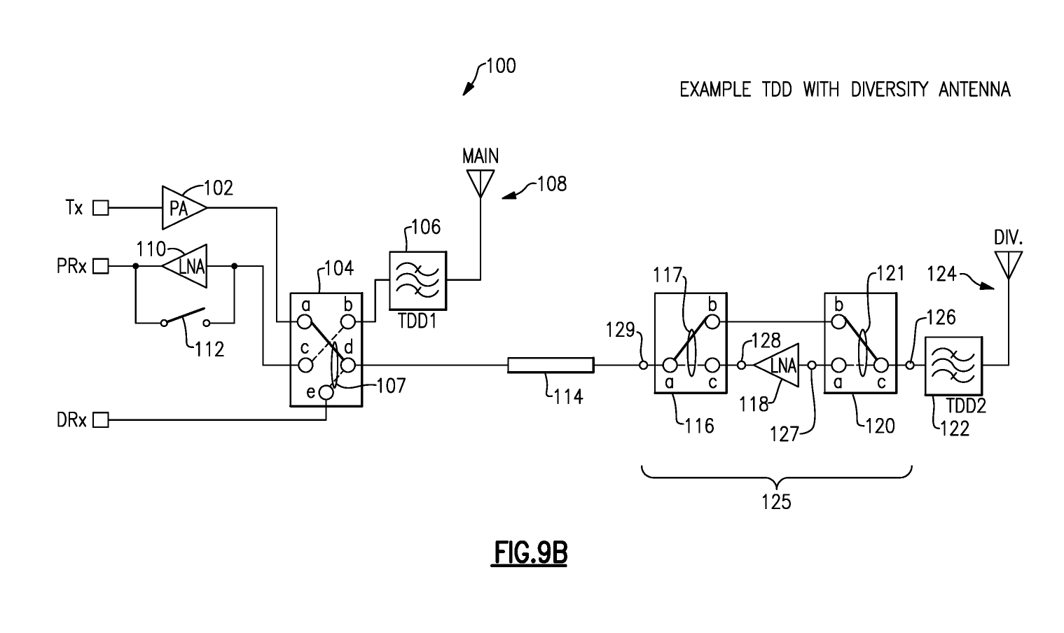

In the example of FIG. 8, Tx operation can be assigned to the main antenna 108 or the diversity antenna 124. Accordingly, switch node 104a can be connected to switch node 104b (depicted as a solid line) or to switch node 104d (also depicted as a solid line). When the main antenna 108 is utilized for Tx operation, Tx and PRx can be time-division duplexed as shown in FIG. 9A. When the diversity antenna 124 is utilized for Tx operation, Tx and DRx can be time-division duplexed as shown in FIG. 9B.

In the example of FIG. 8, switch nodes 120c and 120a of the switch circuit 120 can be connected (depicted as a dashed line), and switch nodes 116c and 116a of the switch circuit 116 can be connected (depicted as a dashed line), when the LNA 118 is to be utilized. Similarly, switch nodes 120c and 120b of the switch circuit 120 can be connected (depicted as a solid line), and switch nodes 116b and 116a of the switch circuit 116 can be connected (depicted as a solid line), when the LNA 118 is to be bypassed.

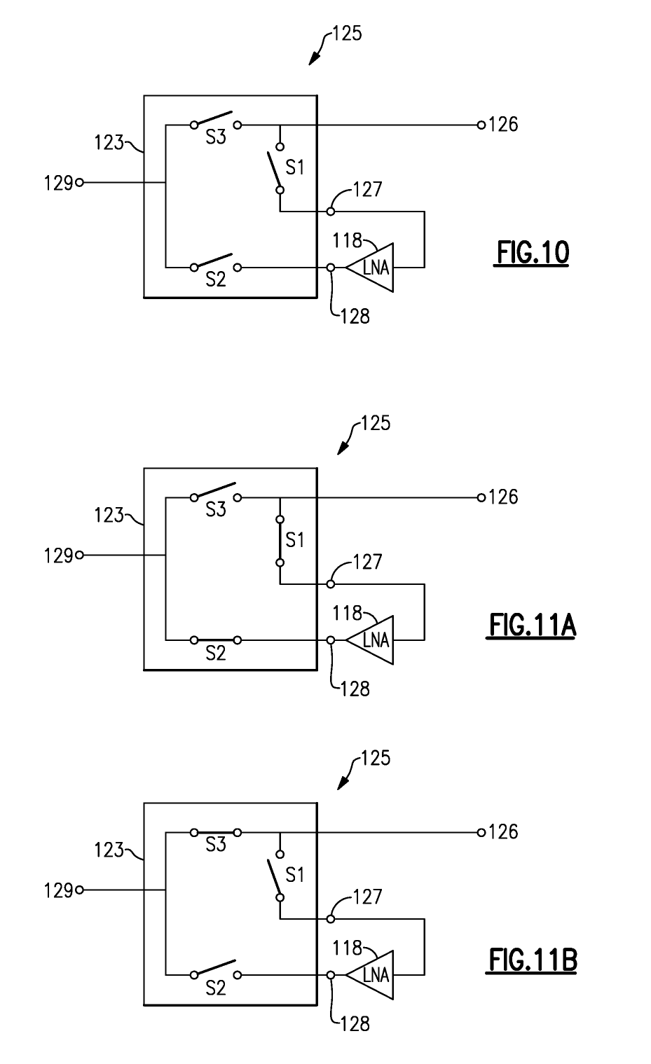

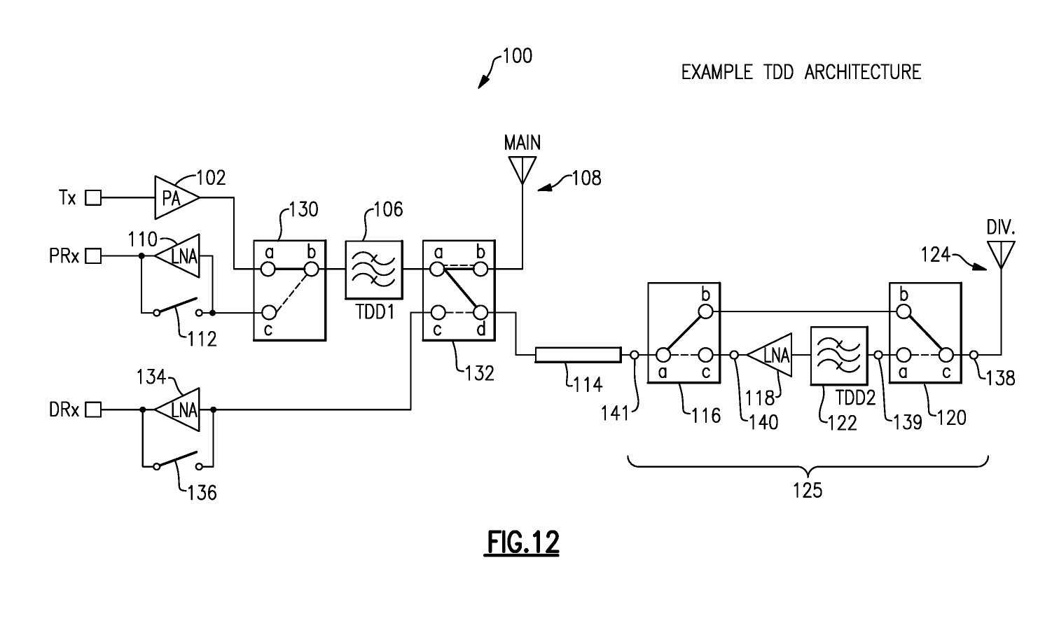

In the example of FIG. 8, the foregoing portion of the TDD antenna routing system 100 involving use of or bypassing of the LNA 118 between nodes 126 and 129 is indicated as 125. An example of a switching scheme that can be utilized for such functionality is shown in FIG. 10. FIGS. 11A and 11B show examples of switching configurations of such a switching scheme for effectuating the example operating modes of FIGS. 9A and 9B.

FIG. 9A shows an example configuration in which the TDD antenna routing system 100 of FIG. 8 utilizes the main antenna 108 for Tx operation. In such a configuration, TDD can be achieved by switching actions (indicated as 105) involving the switch circuit 104. For example, switch nodes 104b and 104a can be connected when the TDD operation is in a Tx mode; and switch nodes 104b and 104c can be connected when the TDD operation is in a PRx mode.

In the example of FIG. 9A, DRx operation can be achieved through the diversity antenna 124. Accordingly, the LNA 118 can be utilized, and to facilitate such LNA operation, switch nodes 120c and 120a of the switch circuit 120, as well as switch nodes 116c and 116a of the switch circuit 116, can be connected as shown.

FIG. 9B shows an example configuration in which the TDD antenna routing system 100 of FIG. 8 utilizes the diversity antenna 124 for Tx operation. In such a configuration, TDD can be achieved by switching actions (indicated as 107) involving the switch circuit 104. For example, switch nodes 104d and 104a can be connected when the TDD operation is in a Tx mode; and switch nodes 104d and 104e can be connected when the TDD operation is in a DRx mode.

In the example of FIG. 9B, PRx operation can be maintained utilizing the main antenna 108. Accordingly, switch nodes 104b and 104c of the switch circuit 104 can remain connected as shown.

In the example of FIG. 9B, the TDD operation involving the diversity antenna 124 can be facilitated by the portion 125 along the DRx amplification path. For example, when the TDD operation is in a Tx mode, the LNA 118 can be bypassed by having switch nodes 120c and 120b of the switch circuit 120 connected (depicted as a solid line), and switch nodes 116b and 116a of the switch circuit 116 connected (depicted as a solid line). When the TDD operation is in a DRx mode, the LNA 118 can amplify the received signal (from the diversity antenna 124) by having switch nodes 120c and 120a of the switch circuit 120 connected (depicted as a dashed line), and switch nodes 116c and 116a of the switch circuit 116 connected (depicted as a dashed line). In some embodiments, the foregoing switching actions (depicted as 121 and 117) for TDD operation can be performed in cooperation with the switching action 107 involving the switch circuit 104.

In the example of FIGS. 8 and 9, there are two filters (TDD1 and TDD2) that can facilitate the various TDD operations. In some embodiments, each of such filters can be configured with sufficient pass-band width to accommodate frequency bands associated with Tx and DRx operations, while providing sufficient performance characteristics. Such frequency bands can overlap, or be separated by a relatively small frequency gap. In the context of overlapping frequency bands, such bands can partially or fully overlap. For example, B38 band (2570 MHz to 2620 MHz) is contained entirely within B41 band (2496 MHz to 2690 MHz). In another example, A-XGP band (2545 MHz to 2575 MHz) overlaps slightly with the B38 band (2570 MHz to 2620 MHz). It will be understood that other combinations of bands can be utilized.

FIG. 10 shows an example of a switching configuration that can be implemented between the nodes 126 and 129 of FIGS. 8 and 9, for the portion 125 of the DRx amplification path. Such a switching configuration can include a switch circuit 123 in which switch S1 can be provided between nodes 126 and 127, with the node 127 being on the input side of the LNA 118. Another switch S2 can be provided between nodes 128 and 129, with the node 128 being on the output side of the LNA 118. Accordingly, the switch S1, the LNA 118, and the switch S2 form one path between the nodes 126 and 129. An electrically parallel path between the nodes 126 and 129 is shown to include a switch S3.

In the foregoing example of FIG. 10, it is noted that relatively low loss can be realized in the bypass path with use of a single switch (S3) when bypassing of the LNA 118 is desired (e.g., during a Tx mode). It is also noted that relatively low loss can also be realized for a signal received through the diversity antenna (124 in FIGS. 8 and 9) and being provided to the LNA 118, with use of a single switch (S1) when the LNA 118 is being utilized (e.g., during a receive mode). It will be understood that other switching configurations can also be utilized.

FIG. 11A shows an example of how the switches S1 to S3 can be operated when the LNA 118 is being utilized (e.g., during a receive mode). In such a mode, S1 and S2 before and after the LNA 118 can be closed, and S3 can be opened. The example configuration of FIG. 11A can correspond to, for example, the DRx phase of the TDD operation described in reference to FIG. 9B. The same configuration of FIG. 11A can also facilitate the DRx operation of FIG. 9A.

FIG. 11B shows an example of how the switches S1 to S3 can be operated when the LNA 118 is being bypassed (e.g., during a Tx mode). In such a mode, S1 and S2 before and after the LNA 118 can be opened, and S3 can be closed. The example configuration of FIG. 11B can correspond to, for example, the Tx phase of the TDD operation (with the diversity antenna) described in reference to FIG. 9B.

In the context of the TDD operation (with the diversity antenna) of FIG. 9B, the TDD switching actions (depicted as 121 and 117) can correspond to switching between the configurations of FIGS. 11A and 11B. As described herein, such TDD switching actions can be performed in cooperation with the switching action 107 of the switch circuit 104 in FIG. 9B.

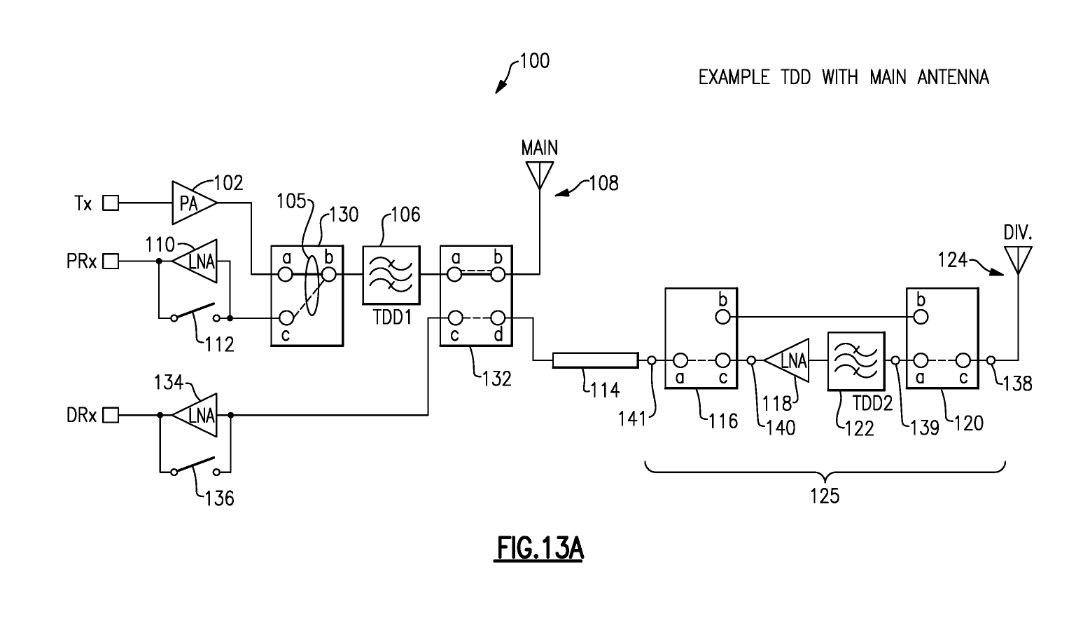

FIG. 12 shows another example TDD antenna routing system 100 that can be implemented with a reduced number of filters. In the example of FIG. 12, functionalities associated with the switch circuit 104 of FIG. 8 can be implemented as first and second switch circuit blocks 130 and 132. In some embodiments, the second switch circuit block 132 can be part of an antenna switch module (ASM); and presence of such a second switch circuit block can provide, among others, support for carrier aggregation (CA).

By way of non-limiting examples, carrier aggregation of a plurality of simultaneous RF paths can be supported through a number of implementations. For example, separate ASMs and band groups of RF paths dedicated to them can be routed to separate antennas and leverage the antenna-to-antenna isolation for further benefit between the separate bands to be carrier aggregated.

In another example, separate ASMs can be combined with another set of grouped bands through another ASM with use of a diplex filter to merge the two RF paths into a single shared common path going to a common antenna feed. If the bands to be aggregated have reasonably large frequency separation, then the bands can be merged to a common antenna feed in this way with fairly low loss.

In yet another example, bands can be permanently “ganged” together at their shared common ANT port and be switched in appropriately. In yet another example, filters can be electrically switched into connection through a use of simultaneous switch throws in common switching circuits (e.g., switching circuits 132, 120 in FIG. 12).

Referring to FIG. 12, the antenna routing system 100 can include a first switching circuit block 130 configured to provide Tx/PRx TDD functionality. For example, switch node 130a can be coupled to a Tx node through a PA 102, and switch node 130c can be coupled to a PRx node through an LNA 110. A bypass path can be provided for the LNA 110 utilizing a switch 112. Switch node 130b can be coupled to a second switching circuit block 132 (e.g., implemented as an ASM) through a first TDD filter (TDD1) 106.

Referring to the second switching circuit block 132 of FIG. 12, switch node 132a can be coupled to the first TDD filter (TDD1) 106, and switch node 132b can be coupled to a main antenna 108. Switch node 132c can be coupled to a DRx node, and switch node 132d can be coupled to a diversity antenna 124 through a switch circuit 120, a second TDD filter (TDD2) 122, an LNA 118, a switch circuit 116, and a relatively lengthy and lossy path indicated as 114.

With the foregoing example configuration of FIG. 12, PRx operation can be assigned to the main antenna 108 by the ASM 132. Accordingly, switch node 132b is shown to be connected to switch node 134a (depicted as a dashed line) during PRx operation. Similarly, DRx operation can be assigned to the diversity antenna 124 by the ASM 132. Accordingly, switch node 132d is shown to be connected to switch node 132c (depicted as a dashed line).

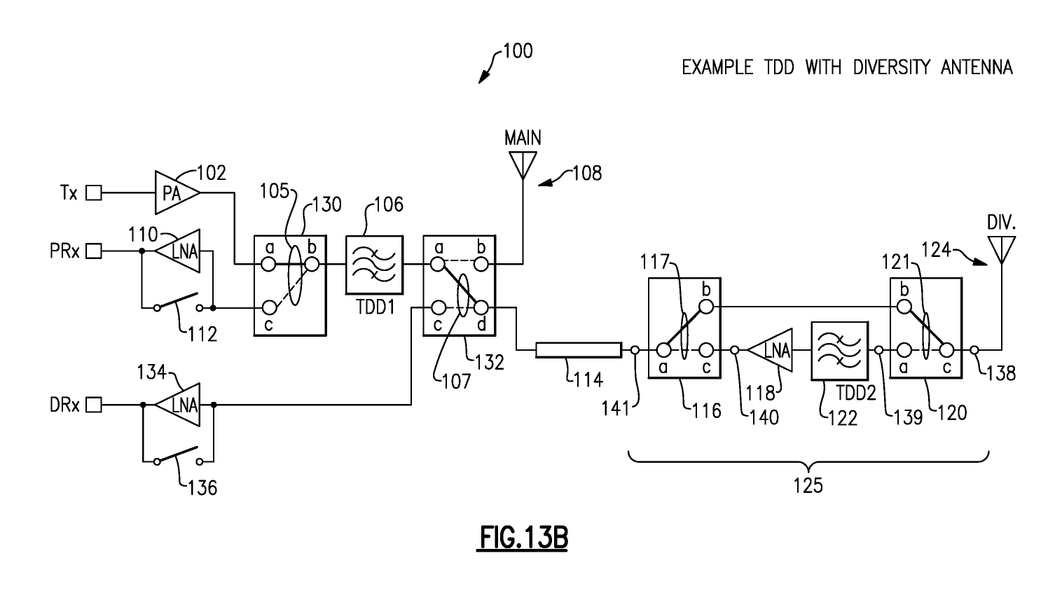

In the example of FIG. 12, Tx operation can be assigned to the main antenna 108 or the diversity antenna 124. Accordingly, switch node 132a can be connected to switch node 132b (depicted as a solid line) or to switch node 132d (also depicted as a solid line). When the main antenna 108 is utilized for Tx operation, Tx and PRx can be time-division duplexed as shown in FIG. 13A. When the diversity antenna 124 is utilized for Tx operation, Tx and DRx can be time-division duplexed as shown in FIG. 13B.

In the example of FIG. 12, switch nodes 120c and 120a of the switch circuit 120 can be connected (depicted as a dashed line), and switch nodes 116c and 116a of the switch circuit 116 can be connected (depicted as a dashed line), when the LNA 118 is to be utilized. Similarly, switch nodes 120c and 120b of the switch circuit 120 can be connected (depicted as a solid line), and switch nodes 116b and 116a of the switch circuit 116 can be connected (depicted as a solid line), when the LNA 118 is to be bypassed.

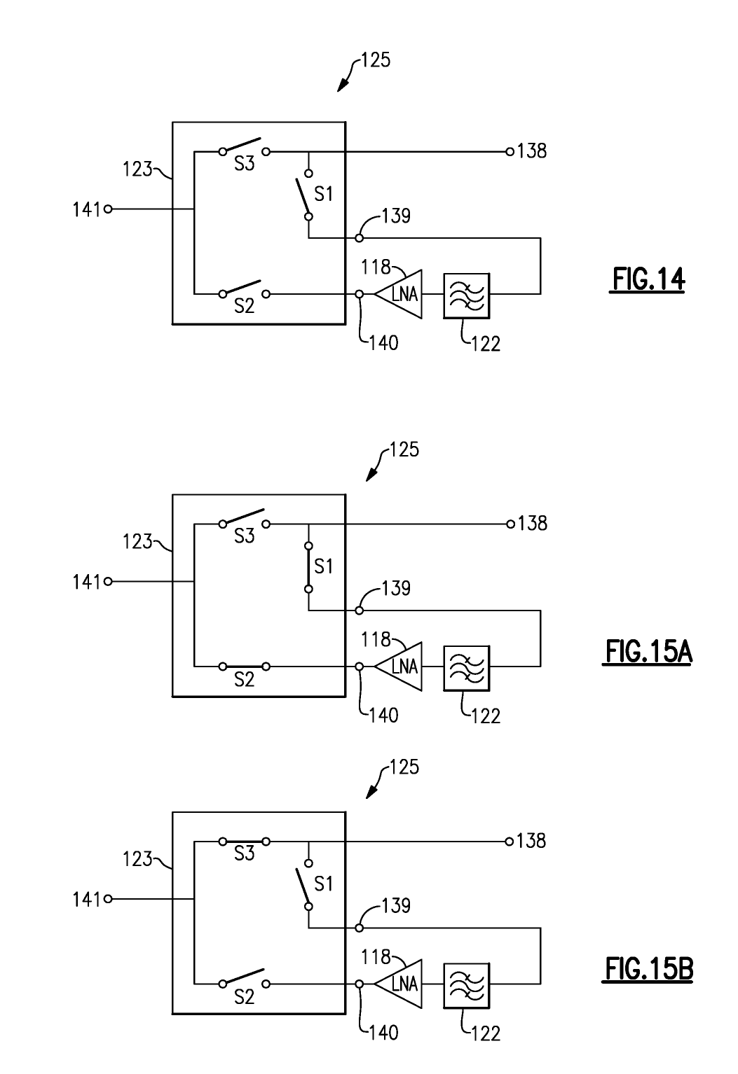

In the example of FIG. 12, the foregoing portion of the TDD antenna routing system 100 involving use of or bypassing of the LNA 118 between nodes 138 and 141 is indicated as 125. An example of a switching scheme that can be utilized for such functionality is shown in FIG. 14. FIGS. 15A and 15B show examples of switching configurations of such a switching scheme for effectuating the example operating modes of FIGS. 13A and 13B.

It is noted that in some embodiments, the example switching functionality provided by, for example, switching circuits 132, 116 and 120 can be extended to support one or more additional RF paths. As described herein, each of such additional RF path(s) can include separate band support and specific filtering as required or desired, simply by addition of switch throws and connectivity.

FIG. 13A shows an example configuration in which the TDD antenna routing system 100 of FIG. 12 utilizes the main antenna 108 for Tx operation. In such a configuration, TDD can be achieved between Tx and PRx modes by switching actions (indicated as 105) involving the Tx/PRx switch circuit 130. For example, switch nodes 130a and 130b can be connected when the TDD operation is in a Tx mode; and switch nodes 130b and 130c can be connected when the TDD operation is in a PRx mode.

In the example of FIG. 13A, the connection of switch nodes 132a and 132b of the ASM 132 allows the Tx/PRx TDD operation to be performed with the main antenna. As described herein, when the Tx operation is to be performed with the diversity antenna, the PRx operation can remain with the main antenna. Accordingly, routing for PRx operation does not necessarily depend on the routing for Tx operation.

In the example of FIG. 13A, DRx operation can be achieved through the diversity antenna 124. Accordingly, the LNA 118 can be utilized, and to facilitate such LNA operation, switch nodes 120c and 120a of the switch circuit 120, as well as switch nodes 116c and 116a of the switch circuit 116, can be connected as shown.

In the example of FIG. 13A, the DRx operation can optionally include a second LNA 134 downstream from the ASM 132. A bypass path can be provided for the LNA 134 utilizing a switch 136.

FIG. 13B shows an example configuration in which the TDD antenna routing system 100 of FIG. 12 utilizes the diversity antenna 124 for Tx operation. In such a configuration, TDD can be achieved between Tx and DRx modes by switching actions (indicated as 107) involving the ASM 132. For example, switch nodes 132d and 132a can be connected when the TDD operation is in a Tx mode; and switch nodes 132d and 132c can be connected when the TDD operation is in a DRx mode.

In the example of FIG. 13B, PRx operation can remain with use of the main antenna 108. Accordingly, switch nodes 132b and 132a of the ASM 132 can remain connected as shown. For the Tx/PRx switch circuit 130, switching action indicated as 105 can be performed in cooperation with the switching action 107 of the ASM 132. Thus, when in a Tx mode, switch nodes 130a and 130b of the Tx/Rx switch circuit 130 can be connected; and when in a PRx mode, switch nodes 130b and 130c of the Tx/Rx switch circuit 130 can be connected.

In the example of FIG. 13B, the TDD operation involving the diversity antenna 124 can be facilitated by the portion 125 along what is normally a DRx amplification path. For example, when the TDD operation is in a Tx mode, the second TDD filter (TDD2) 122 and the LNA 118 can be bypassed by having switch nodes 120c and 120b of the switch circuit 120 connected (depicted as a solid line), and switch nodes 116b and 116a of the switch circuit 116 connected (depicted as a solid line). When the TDD operation is in a receive mode, the LNA 118 can amplify the received signal (from the diversity antenna 124), filtered by the second TDD filter (TDD2) 122, by having switch nodes 120c and 120a of the switch circuit 120 connected (depicted as a dashed line), and switch nodes 116c and 116a of the switch circuit 116 connected (depicted as a dashed line). In some embodiments, the foregoing switching actions (depicted as 121 and 117) for TDD operation can be performed in cooperation with the switching action 107 involving the ASM 132.

In the example of FIGS. 12 and 13, there are two filters (TDD1 and TDD2) that can facilitate the various TDD operations. The second TDD filter (TDD2) 122 is shown to be bypassed completely when Tx operation is being performed through the diversity antenna 124. Thus, the two filters (TDD1 and TDD2) may or may not be configured to have overlapping frequency bands. For example, frequency bands associated with Tx and DRx modes do not need to overlap.

In some embodiments, the foregoing configuration of filters can be utilized in lower power applications such as machine type communications that utilize half-duplex operation such as TDD operation. Such applications can utilize TDD operation between separate paired bands of normally TDD spectrum to, for example, relax filtering requirements and self-desense degradation.

FIG. 14 shows an example of a switching configuration that can be implemented between the nodes 138 and 141 of FIGS. 12 and 13, for the portion 125 of the DRx amplification path. Such a switching configuration can include a switch circuit 123 in which switch S1 can be provided between nodes 138 and 139, with the node 139 being on the input side of the LNA 118 (through the filter 122). Another switch S2 can be provided between nodes 140 and 141, with the node 140 being on the output side of the LNA 118. Accordingly, the switch S1, the filter 122, the LNA 118, and the switch S2 form one path between the nodes 138 and 141. An electrically parallel path between the nodes 138 and 141 is shown to include a switch S3.

In the foregoing example of FIG. 14, it is noted that relatively low loss can be realized in the bypass path with use of a single switch (S3) when bypassing of the LNA 118 is desired (e.g., during a Tx mode). It is also noted that relatively low loss can also be realized for a signal received through the diversity antenna (124) and being provided to the LNA 118, with use of a single switch (S1) when the LNA 118 is being utilized (e.g., during a receive mode). It will be understood that other switching configurations can also be utilized.

FIG. 15A shows an example of how the switches S1 to S3 can be operated when the LNA 118 is being utilized (e.g., during a receive mode). In such a mode, S1 and S2 before and after the LNA 118 can be closed, and S3 can be opened. The example configuration of FIG. 15A can correspond to, for example, the DRx phase of the TDD operation described in reference to FIG. 13B. The same configuration of FIG. 15A can also facilitate the DRx operation of FIG. 13A.

FIG. 15B shows an example of how the switches S1 to S3 can be operated when the LNA 118 is being bypassed (e.g., during a Tx mode). In such a mode, S1 and S2 before and after the LNA 118 can be opened, and S3 can be closed. The example configuration of FIG. 15B can correspond to, for example, the Tx phase of the TDD operation (with the diversity antenna) described in reference to FIG. 13B.

In the context of the TDD operation (with the diversity antenna) of FIG. 13B, the TDD switching actions (depicted as 121 and 117) can correspond to switching between the configurations of FIGS. 15A and 15B. As described herein, such TDD switching actions can be performed in cooperation with the switching action 107 of the switch circuit 132 in FIG. 13B.

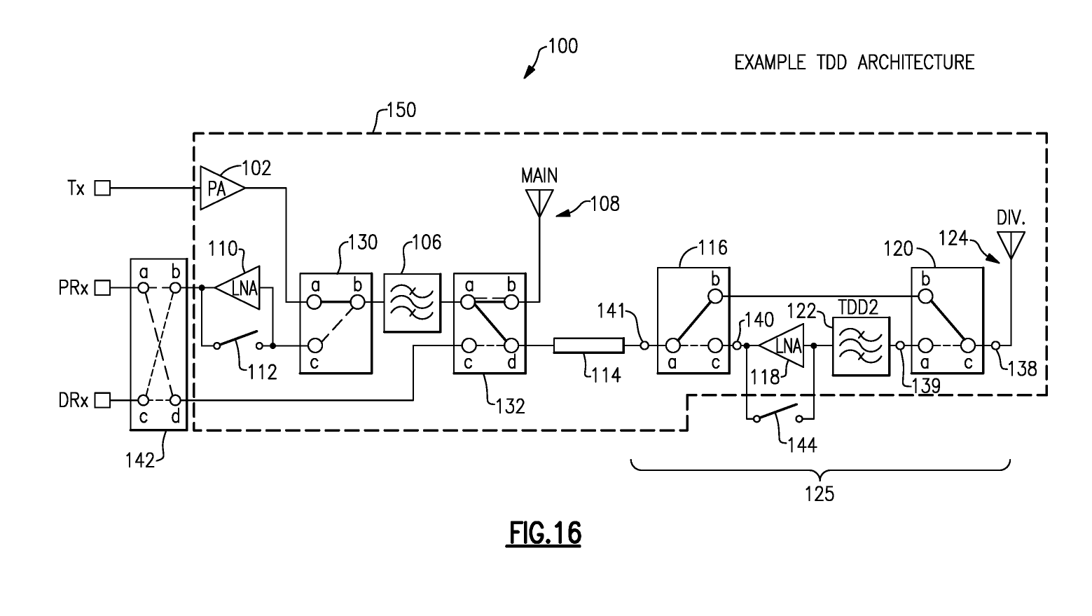

FIG. 16 shows yet another example TDD antenna routing system 100 that can be implemented with a reduced number of filters. In the example of FIG. 16, the portion within the dashed boundary 150 can be similar to the example of FIG. 12. Accordingly, various examples related to such a portion of the TDD antenna routing system 100 are described in reference to FIGS. 12 and 13.

In the example TDD antenna routing systems described in reference to FIGS. 8, 9, 12 and 13, one can see that other connections can be made between the Rx nodes and the antennas, in addition to the ones described, by appropriate operations of the various switching circuits. For example, and referring to FIGS. 9B and 13B, in which Tx operation is being achieved through the diversity antenna, the PRx amplification path from the main antenna can function as an amplification path for a DRx band. Similarly, the DRx amplification path from the diversity antenna can function as an amplification path for a PRx band. However, such swapping of PRx and DRx functionality results in the DRx signal being output to the PRx pin, and the PRx signal being output to the DRx pin.

In the example of FIG. 16, a PRx/DRx switching circuit 142 is shown to be implemented relative to the PRx and DRx nodes. Such a switching circuit can be implemented in a cross-point configuration, and great flexibility can be achieved in possible connections between antennas (e.g., main and diversity) and Rx pins (e.g., PRx and DRx nodes). Such flexibility can include, for example, a DRx signal being output to the DRx pin even if it was obtained from the main antenna. Similarly, a PRx signal can be output to the PRx pin even if it was obtained from the diversity antenna.

Table 1 lists non-limiting examples of various connection configurations.

TABLE 1

| Configu- | PRx | DRx | PRx | DRx | |
|---|---|---|---|---|---|
| ration | connection | connection | pin | pin | Connection |
| Nominal | PRx to | DRx to | ON | OFF | Main to PRx pin |
| | Main | Diversity | | | |
| Swapped | PRx to | DRx to | ON | OFF | Diversity to PRx pin |
| | Diversity | Main | | | |
| Nominal | PRx to | DRx to | OFF | ON | Diversity to DRx pin |
| | Main | Diversity | | | |
| Swapped | PRx to | DRx to | OFF | ON | Main to DRx pin |
| | Diversity | Main | | | |
| Nominal | PRx to | DRx to | ON | ON | Main to PRx pin + |
| | Main | Diversity | | | Diversity to DRx pin |
| Swapped | PRx to | DRx to | ON | ON | Diversity to PRx pin + |
| | Diversity | Main | | | Main to DRx pin |

In Table 1, the first example configuration is a nominal configuration where a PRx signal originating from the main antenna and being output at the PRx pin is desired, with the DRx pin being OFF. Such a configuration can be achieved by, for example, TDD operation between Tx and PRx signal with the main antenna as described herein, and the DRx path being disabled. In the PRx/DRx switching circuit 142, switch nodes 142a and 142b can be connected, and all other switch nodes can be disconnected, to achieve such a configuration.

In Table 1, the second example configuration is a swapped configuration where a PRx signal originating from the diversity antenna and being output at the PRx pin is desired, with the DRx pin being OFF. Such a configuration can be achieved by, for example, TDD operation between Tx and PRx signal with the diversity antenna, and the PRx path being disabled. In the PRx/DRx switching circuit 142, switch nodes 142d and 142a can be connected, and all other switch nodes can be disconnected, to achieve such a configuration.

In Table 1, the third example configuration is a nominal configuration where a DRx signal originating from the diversity antenna and being output at the DRx pin is desired, with the PRx pin being OFF. Such a configuration can be achieved by, for example, TDD operation of the DRx signal with the diversity antenna, and the PRx path being disabled. In the PRx/DRx switching circuit 142, switch nodes 142d and 142c can be connected, and all other switch nodes can be disconnected, to achieve such a configuration.

In Table 1, the fourth example configuration is a swapped configuration where a DRx signal originating from the main antenna and being output at the DRx pin is desired, with the PRx pin being OFF. Such a configuration can be achieved by, for example, TDD operation of the DRx signal with the main antenna, and the DRx path being disabled. In the PRx/DRx switching circuit 142, switch nodes 142b and 142c can be connected, and all other switch nodes can be disconnected, to achieve such a configuration.

In Table 1, the fifth example configuration is a nominal configuration where a PRx signal originating from the main antenna and being output at the PRx pin, as well as a DRx signal originating from the diversity antenna and being output at the DRx pin, are desired. Such a configuration can be achieved by, for example, TDD operation between Tx and PRx signal with the main antenna, with switch nodes 142b and 142a being connected in the PRx/DRx switching circuit 142; and the DRx path being operational to process a DRx signal, with switch nodes 142d and 142c being connected in the PRx/DRx switching circuit 142.

In Table 1, the sixth example configuration is a swapped configuration where a PRx signal originating from the diversity antenna and being output at the PRx pin, as well as a DRx signal originating from the main antenna and being output at the DRx pin, are desired. Such a configuration can be achieved by, for example, TDD operation between Tx and PRx signal with the diversity antenna, with switch nodes 142d and 142a being connected in the PRx/DRx switching circuit 142; and the PRx path being operational to process a DRx signal, with switch nodes 142b and 142c being connected in the PRx/DRx switching circuit 142.

Among others, the foregoing examples in reference to FIG. 16 and Table 1 show that a given Rx signal can be output to either of the PRx and DRx pins. Further, one or both of such Rx signals can be generated together. Thus, if a fixed pin assignment is desired (e.g., have a PRx signal be output only at the PRx pin, and a DRx signal be output only at the DRx pin), the example configuration of FIG. 16 can advantageously accommodate such design requirements.

In some implementations, an architecture, device and/or circuit having one or more features described herein can be included in an RF device such as a wireless device. Such an architecture, device and/or circuit can be implemented directly in the wireless device, in one or more modular forms as described herein, or in some combination thereof. In some embodiments, such a wireless device can include, for example, a cellular phone, a smart-phone, a hand-held wireless device with or without phone functionality, a wireless tablet, a wireless router, a wireless modem configured to support machine type communications, a wireless access point, a wireless base station, etc. Although described in the context of wireless devices, it will be understood that one or more features of the present disclosure can also be implemented in other RF systems such as base stations.

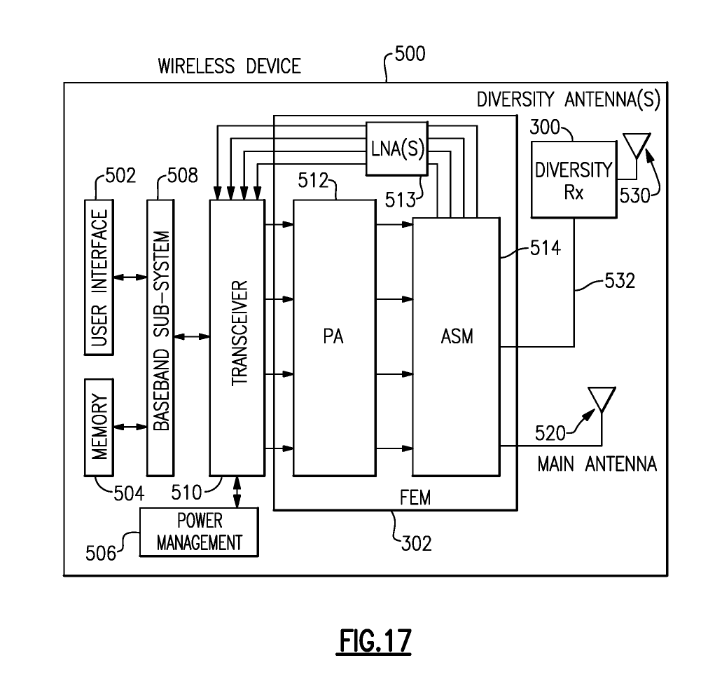

FIG. 17 depicts an example wireless device 500 having one or more advantageous features described herein. In some embodiments, such advantageous features can be implemented in a front-end (FE) module 302, a diversity Rx module 300, or any combination thereof. The FEM 302 is shown to include a power amplifier (PA) module 512, an antenna switch module (ASM) 514, and one or more low-noise amplifiers (LNAs) 513.

As described herein, the diversity Rx module 300 can be configured so that its LNA is relatively close to a diversity antenna 530 which is preferably positioned relatively far from a main antenna 520. Such a diversity module can be configured to provide, for example, bypassing functionalities associated with TDD operations involving Tx and signals received through the diversity antenna 520.

PAs in the PA module 512 can receive their respective RF signals from a transceiver 510 that can be configured and operated to generate RF signals to be amplified and transmitted, and to process received signals. The transceiver 510 is shown to interact with a baseband sub-system 508 that is configured to provide conversion between data and/or voice signals suitable for a user and RF signals suitable for the transceiver 510. The transceiver 510 is also shown to be connected to a power management component 506 that is configured to manage power for the operation of the wireless device 500. Such power management can also control operations of the baseband sub-system 508 and other components of the wireless device 500.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

One or more features of the present disclosure can be implemented with various cellular frequency bands as described herein. Examples of such bands are listed in Table 2. It will be understood that at least some of the bands can be divided into sub-bands. It will also be understood that one or more features of the present disclosure can be implemented with frequency ranges that do not have designations such as the examples of Table 2.

TABLE 2

| | | Tx Frequency | Rx Frequency |
|---|---|---|---|
| Band | Mode | Range (MHz) | Range (MHz) |
| B1 | FDD | 1,920-1,980 | 2,110-2,170 |
| B2 | FDD | 1,850-1,910 | 1,930-1,990 |
| B3 | FDD | 1,710-1,785 | 1,805-1,880 |
| B4 | FDD | 1,710-1,755 | 2,110-2,155 |
| B5 | FDD | 824-849 | 869-894 |
| B6 | FDD | 830-840 | 875-885 |
| B7 | FDD | 2,500-2,570 | 2,620-2,690 |
| B8 | FDD | 880-915 | 925-960 |
| B9 | FDD | 1,749.9-1,784.9 | 1,844.9-1,879.9 |
| B10 | FDD | 1,710-1,770 | 2,110-2,170 |
| B11 | FDD | 1,427.9-1,447.9 | 1,475.9-1,495.9 |
| B12 | FDD | 699-716 | 729-746 |
| B13 | FDD | 777-787 | 746-756 |
| B14 | FDD | 788-798 | 758-768 |
| B15 | FDD | 1,900-1,920 | 2,600-2,620 |
| B16 | FDD | 2,010-2,025 | 2,585-2,600 |
| B17 | FDD | 704-716 | 734-746 |
| B18 | FDD | 815-830 | 860-875 |
| B19 | FDD | 830-845 | 875-890 |
| B20 | FDD | 832-862 | 791-821 |
| B21 | FDD | 1,447.9-1,462.9 | 1,495.9-1,510.9 |
| B22 | FDD | 3,410-3,490 | 3,510-3,590 |
| B23 | FDD | 2,000-2,020 | 2,180-2,200 |
| B24 | FDD | 1,626.5-1,660.5 | 1,525-1,559 |
| B25 | FDD | 1,850-1,915 | 1,930-1,995 |
| B26 | FDD | 814-849 | 859-894 |
| B27 | FDD | 807-824 | 852-869 |
| B28 | FDD | 703-748 | 758-803 |
| B29 | FDD | N/A | 716-728 |
| B30 | FDD | 2,305-2,315 | 2,350-2,360 |
| B31 | FDD | 452.5-457.5 | 462.5-467.5 |
| B32 | FDD | N/A | 1,452-1,496 |
| B33 | TDD | 1,900-1,920 | 1,900-1,920 |
| B34 | TDD | 2,010-2,025 | 2,010-2,025 |
| B35 | TDD | 1,850-1,910 | 1,850-1,910 |
| B36 | TDD | 1,930-1,990 | 1,930-1,990 |
| B37 | TDD | 1,910-1,930 | 1,910-1,930 |
| B38 | TDD | 2,570-2,620 | 2,570-2,620 |
| B39 | TDD | 1,880-1,920 | 1,880-1,920 |
| B40 | TDD | 2,300-2,400 | 2,300-2,400 |
| B41 | TDD | 2,496-2,690 | 2,496-2,690 |
| B42 | TDD | 3,400-3,600 | 3,400-3,600 |
| B43 | TDD | 3,600-3,800 | 3,600-3,800 |
| B44 | TDD | 703-803 | 703-803 |

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. An antenna routing architecture comprising:
first nodes including a transmit node, a primary receive node and a diversity receive node;
second nodes including a main antenna node and a diversity antenna node; and
a routing circuit configured to provide one or more radio-frequency signal paths between the first nodes and the second nodes, the routing circuit further configured such that each of the transmit node and the primary receive node is capable of being independently coupled to the main antenna node or the diversity antenna node.

2. The antenna routing architecture of claim 1 wherein the routing circuit is further configured to include duplexing functionality.

3. The antenna routing architecture of claim 2 wherein the duplexing functionality includes time-division duplexing functionality.

4. The antenna routing architecture of claim 3 wherein the primary receive node is coupled to the main antenna node, and the diversity receive node is coupled to the diversity antenna node.

5. The antenna routing architecture of claim 4 wherein the primary receive node is always coupled to the main antenna node, and the diversity receive node is always coupled to the diversity antenna node.

6. The antenna routing architecture of claim 4 wherein the routing circuit includes a first switching circuit configured to couple the transmit node to the main antenna node or the diversity antenna node.

7. The antenna routing architecture of claim 6 wherein the first switching circuit is further configured to provide the coupling of the primary receive node to the main antenna node, and to provide the coupling of the diversity receive node to the diversity antenna node.

8. The antenna routing architecture of claim 6 wherein the routing circuit includes a first time-division duplexing filter implemented between the first switching circuit and the main antenna node.

9. The antenna routing architecture of claim 8 wherein the first time-division duplexing filter is configured to allow time-division duplexing operation involving an amplified transmit signal associated with the transmit node and a receive signal associated with the primary receive node when the main antenna node is being utilized for the time-division duplexing operation.

10. The antenna routing architecture of claim 8 wherein the routing circuit further includes a lossy path between the first switching circuit and the diversity receive node.

11. The antenna routing architecture of claim 10 wherein the routing circuit further includes a low-noise amplifier implemented between the lossy path and the diversity receive node, the low-noise amplifier configured to provide amplification for a receive signal received through the diversity receive node.

12. The antenna routing architecture of claim 11 wherein the routing circuit further includes a switchable path configured to selectively bypass the low-noise amplifier.

13. The antenna routing architecture of claim 12 wherein the routing circuit includes a bypass switch assembly implemented to allow routing of the receive signal from the diversity receive node to the low-noise amplifier, or to allow routing of an amplified transmit signal associated with the transmit node through the switchable bypass path.

14. The antenna routing architecture of claim 13 wherein the bypass switch assembly includes a first switch between the diversity receive node and the low-noise amplifier, and a second switch parallel with the first switch and between the diversity receive node and the lossy path.

15. The antenna routing architecture of claim 14 wherein the first switch is the only switch between the diversity receive node and the low-noise amplifier, such that the receive signal experiences a relatively low loss due to the only switch.

16. The antenna routing architecture of claim 15 wherein the bypass switch assembly further includes a third switch between the low-noise amplifier and the lossy path.

17. The antenna routing architecture of claim 14 wherein the second switch is the only switch between the lossy path and the diversity receive node, such that the amplified transmit signal experiences a relatively low loss due to the only switch.

18. The antenna routing architecture of claim 13 wherein the routing circuit further includes a second time-division duplexing filter implemented between the first bypass switch and the diversity receive node.

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. A method for performing time-division duplexing of radio-frequency signals, the method comprising:
maintaining a primary receive connectivity to a main antenna;
maintaining a diversity receive connectivity to a diversity antenna; and
swapping a transmit connectivity between the main antenna and the diversity antenna.

51. (canceled)

52. (canceled)

53. A wireless device comprising:
a transceiver configured to process radio-frequency signals;
a main antenna and a diversity antenna, each in communication with the transceiver; and
an antenna routing system implemented between the transceiver and the main and diversity antennas, the antenna routing system including first nodes having a transmit node, a primary receive node and a diversity receive node, the antenna routing system further including second nodes having a main antenna node and a diversity antenna node, the antenna routing system further including a routing circuit configured to provide one or more radio-frequency signal paths between the first nodes and the second nodes, the routing circuit further configured such that each of the node and the primary receive node is capable of being independently coupled to the main antenna node or the diversity antenna node.

54. (canceled)

55. (canceled)
